(19) United States
(12) Patent Application Publication
(10) Pub. No.: US 2013/0257525 A1
(43) Pub. Date: Oct. 3, 2013

(54) CIRCUIT BOARD WITH INTEGRATED VOLTAGE REGULATOR

(71) Applicants: Stephen V. Kosonocky, Fort Collins, CO (US); Noah Sturcken, New York, NY (US)

(72) Inventors: Stephen V. Kosonocky, Fort Collins, CO (US); Noah Sturcken, New York, NY (US)

(21) Appl. No.: 13/436,195

(22) Filed: Mar. 30, 2012

(51) Int. Cl. G05F 1/10; H05K 3/30

(52) U.S. Cl. 327/540; 29/832

(57) ABSTRACT

Various circuit board voltage regulators and methods of making and using the same are disclosed. In one aspect, a method of manufacturing is provided that includes fabricating at least one inductor in a circuit board and coupling a semiconductor chip to the circuit board. The at least one inductor is electrically coupled to the semiconductor chip. Regulator logic is electrically coupled to the at least one inductor, the regulator logic and the at least one inductor are operable to deliver a regulated voltage to the semiconductor chip.

### BACKGROUND OF THE INVENTION

1. Field of the Invention

This invention relates generally to semiconductor processing, and more particularly to circuit board voltage regulators and to methods of making and using the same.

2. Description of the Related Art

Conventional integrated circuits are frequently implemented on a semiconductor substrate or die that consists of a small, often rectangular, piece of semiconductor material, typically silicon, fashioned with two opposing principal sides. The active circuitry for the die is concentrated near one of the two principal sides. A conventional die is usually mounted on some form of substrate, such as a package substrate or a printed circuit board. Electrical conductivity between the die and the underlying substrate or board is established through a variety of conventional mechanisms. In a so-called flip-chip configuration, the active circuitry side of the die is provided with a plurality of conductor balls or bumps that are designed to establish a metallurgical bond with a corresponding plurality of conductor pads positioned on the substrate or circuit board. The die is flipped over and seated on the underlying substrate with the active circuitry side facing downwards. A subsequent thermal process is performed to establish the requisite metallurgical bond between the bumps and the pads. One of the principal advantages of a flip-chip mounting strategy is the relatively short electrical pathways between the integrated circuit and the substrate. These relatively low inductance pathways yield a high speed performance for the electronic device.

Power is supplied to the substrate or circuit board from some external power supply, which might be on or connected to a system board. The input power is typically produced by a voltage regulator on the system board. A 3.3 volt regulated voltage is typical of present-day power supplies for integrated circuits. However, conventional semiconductor chips often require power at different voltage levels. Providing a regulated step down voltage, from say a 3.3 volt input, can produce surprisingly high currents. For example, an integrated circuit operating at 100 watts and 1 volt may draw nearly 100 amps of current. Conventional voltage regulators usually include an inductor and switching logic to charge and discharge the inductor according to some algorithm.

It would be desirable to incorporate a regulator inductor into a semiconductor chip. However, integrated inductors for high current applications require very low resistance thick metals that are typically not present in today's semiconductor chip processing technologies. For example, current CMOS processes create top metal layers of too high a resistance to serve as an inductor without unacceptable I²R losses. Some conventional designs incorporate magnetic core inductors into a semiconductor chip. Such devices may have current limitations due to device geometry. Still other designs use inductors mounted to the surface of a package substrate, albeit with an attendant performance penalty associated with the path length from the inductor to the chip input/outputs (I/Os) where the regulated voltage is needed.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes fabricating at least one inductor in a circuit board and coupling a semiconductor chip to the circuit board. The at least one inductor is electrically coupled to the semiconductor chip. Regulator logic is electrically coupled to the at least one inductor, the regulator logic and the at least one inductor are operable to deliver a regulated voltage to the semiconductor chip.

In accordance with another aspect of an embodiment of the present invention, a method of providing a regulated voltage to a semiconductor chip is provided that includes coupling the semiconductor chip to a circuit board. The circuit board has at least one onboard inductor. The at least one inductor is electrically coupled to the semiconductor chip. Regulator logic is coupled to the at least one inductor. An input voltage is supplied to the regulator logic. The regulator logic and the at least one inductor are operable to deliver a regulated voltage to the semiconductor chip based on the input voltage.

In accordance with another aspect of an embodiment of the present invention, an apparatus is provided that includes a circuit board that has at least one onboard inductor. A semiconductor chip is coupled to the circuit board and electrically coupled to the at least one inductor. Regulator logic is electrically coupled to the at least one inductor. The regulator logic and the at least one inductor are operable to deliver a regulated voltage to the semiconductor chip.

In accordance with another aspect of an embodiment of the present invention, an apparatus is provided that includes a circuit board that has at least one onboard inductor. The circuit board is adapted to from part of a voltage regulator when coupled to an integrated circuit including regulator logic.

In accordance with another aspect of an embodiment of the present invention, an apparatus is provided that includes a semiconductor chip has regulator logic. The semiconductor chip is adapted to be coupled to an inductor included in a circuit board. The regulator logic when coupled to the at least one inductor is operable to deliver a regulated voltage to the semiconductor chip.

### BRIEF DESCRIPTION OF THE DRAWINGS

The foregoing and other advantages of the invention will become apparent upon reading the following detailed description and upon reference to the drawings in which:

FIG. 1 is a schematic view of an exemplary embodiment of a semiconductor chip device that includes a semiconductor chip coupled to a circuit board;

FIG. 2 is a view of an exemplary embodiment of a semiconductor chip device that includes a semiconductor chip coupled to a circuit board;

FIG. 3 is a sectional view of an exemplary embodiment of a semiconductor chip device that includes a semiconductor chip coupled to a circuit board and onboard inductors;

FIG. 4 is a pictorial schematic view of exemplary build up layers and an exemplary semiconductor chip and depicting exemplary arrangements of regulated voltage pathways;

FIG. 5 is a pictorial schematic view of an exemplary build up layer with an alternate exemplary inductor configuration;

FIG. 6 is a sectional view of an alternate exemplary embodiment of a semiconductor chip device that includes a semiconductor chip coupled to a circuit board and onboard inductors; and

FIG. 7 is a pictorial view depicting an exemplary semiconductor chip device exploded from an exemplary electronic device.

### DETAILED DESCRIPTION OF SPECIFIC EMBODIMENTS

Various types of circuit boards, such as a package substrates, incorporate one or more inductors that assist in supplying a regulated output voltage to a semiconductor chip are disclosed. In one arrangement, the inductors are fabricated in a build up layer of a package substrate and tied electrically to voltage regulator logic, which may be positioned on or off chip. The voltage regulator logic and the inductors function as a buck regulator. The inductors may also be fabricated in the package substrate core as drop-in components or from plated-through-holes. Additional details will now be described.

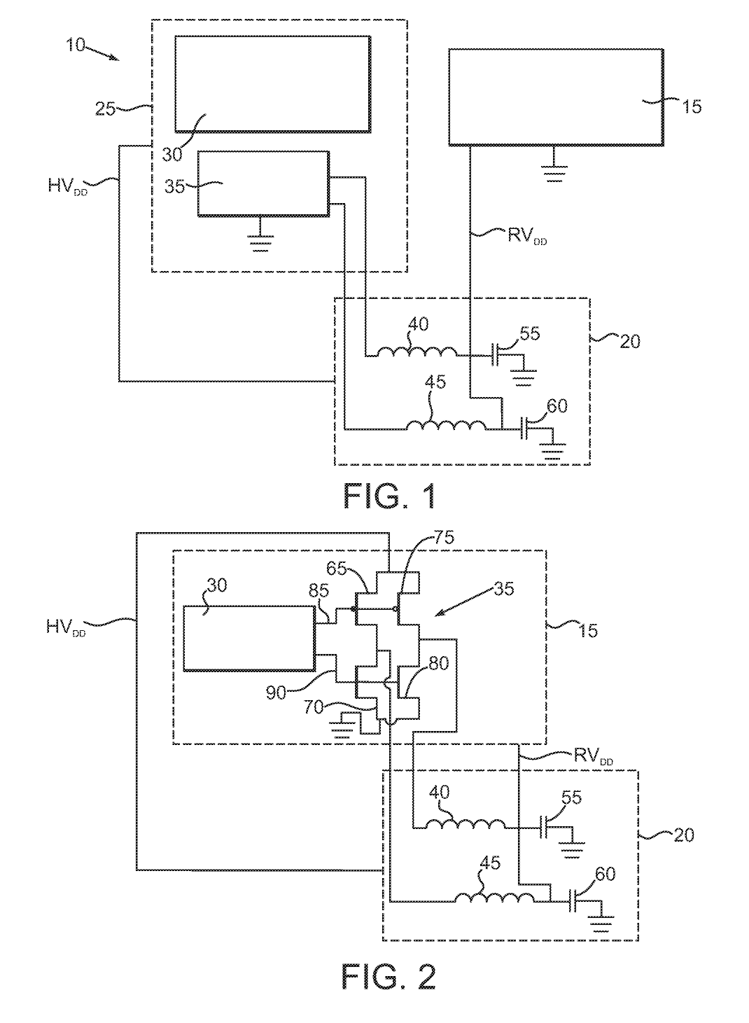

In the drawings described below, reference numerals are generally repeated where identical elements appear in more than one figure. Turning now to the drawings, and in particular to FIG. 1, therein is shown a schematic view of an exemplary embodiment of a semiconductor chip device 10 that includes a semiconductor chip 15 coupled to a circuit board 20. The semiconductor chip device 10 further includes voltage regulator logic 25 that includes a controller 30 and switching logic 35. The voltage regulator logic 25 is electrically connected to a pair of inductors 40 and 45 that are positioned on board the circuit board 20. The common output 50 of the inductors 40 and 45 is provided as an input to the semiconductor chip 15 as a regulated voltage. The outputs of the inductors 40 and 45 are also tied to ground by way of respective capacitors 55 and 60. The capacitors could be internal or external to the circuit board 20. A power input HV_{DD} to the regulator logic 25 is provided by the circuit board 20. Thus, the regulator logic 25 is operable to receive the voltage input HV_{DD} and by way of the controller 30, the switching logic 35 and the inductors 40 and 45 deliver a regulated voltage RV_{DD} as an input to the semiconductor chip 15. The controller 30, the switching logic 35 and the inductors 40 and 45 are configured to function as a buck regulator as described more fully below. The controller 30 may be implemented on the semiconductor chip 15 or as a discrete component. The switching logic 35 may be similarly implemented on the semiconductor chip 15 or as a discrete component. Indeed the controller 30 and the switching logic 35 may be integrated into a single device that is integrated into the semiconductor chip 15.

None of the embodiments disclosed herein is reliant on a particular functionality of the semiconductor chip 15 or the circuit board 20. Thus, the semiconductor chip 15 may be any of a variety of different types of circuit devices used in electronics, such as, for example, interposers, microprocessors, graphics processors, combined microprocessor/graphics processors, application specific integrated circuits, memory devices or the like, and may be single or multi-core. The semiconductor chip 15 may be constructed of bulk semiconductor, such as silicon or germanium, or semiconductor on insulator materials, such as silicon-on-insulator materials or even insulator materials. Thus, the term “semiconductor chip” also contemplates insulating materials. Here, the semiconductor chip device 10 includes the semiconductor chip 15, but additional semiconductor chips may be stacked thereon.

The circuit board 20 may be a semiconductor chip package substrate, a circuit card, or virtually any other type of printed circuit board. Monolithic structures, such as those made of ceramics or polymers could be used. Alternatively, well-known build-up designs may be used. In this regard, the circuit board 20 may consist of a central core upon which one or more build-up layers are formed and below which an additional one or more build-up layers are formed. The core itself may consist of a stack of one or more layers. So-called “coreless” designs may be used as well. The layers of the circuit board 20 may consist of an insulating material, such as various well-known epoxies or other resins interspersed with metal interconnects. A multi-layer configuration other than buildup could be used.

As noted above, the regulator logic 25 may be incorporated into the semiconductor chip if desired. As shown in FIG. 2, which is a schematic view, the regulator logic 25 including the controller 30 and a particular implementation of the switching logic 35 may be incorporated into the semiconductor chip 15. The inductors 40 and 45 as well as the capacitors 55 and 60 may be fabricated onboard the circuit board 20. The switching logic 35 may consist of transistors 65 and 70 connected in parallel with transistors 75 and 80. The transistors 65, 70, 75 and 80 may be field effect transistors, bi-polar transistors or other types of switching devices as desired. Assume for the purposes of this illustration that the transistors 65, 70, 75 and 80 are field effect transistors, and the transistor 65 is an enhancement mode and the transistor 75 is a depletion mode. The outputs 85 and 90 of the controller 30 may be used to turn the transistors 65, 70, 75 and 80 on and off to provide a functionality as described below. For example, when the output 85 is high, the gate of the transistor 65 is turned on and a voltage is supplied to the inductor 45, and the gate of the transistor 75 is off. While the transistor 65 is on, the voltage on the inductor 45 will rise to some level. At the same time, the output 90 of the controller 30 is initially held low so that the transistor 70 is turned off and the transistor 80 is similarly turned off. Following some appropriate period of time during which the voltage on the inductor 45 reaches a desired level, the output 85 from the controller 30 is swung low to shut off the transistor 65 and the output 90 of the controller 30 is swung high to turn on the transistor 70 and thus ground the output of the transistor 65. Since the transistor 75 is in a depletion mode transistor, the swinging of the output 85 low turns on the transistor 75 which then allows the inductor 40 to begin charging. This state is held until the voltage on the inductor 40 reaches some desired level and then the process is reversed and so on and so forth. The usage of dual inductors and the aforementioned switching logic enables the voltage output RV_{DD} to be more uniform since the output RV_{DD} is the combination of the rising and falling of the voltages on the two inductors 40 and 45 over time.

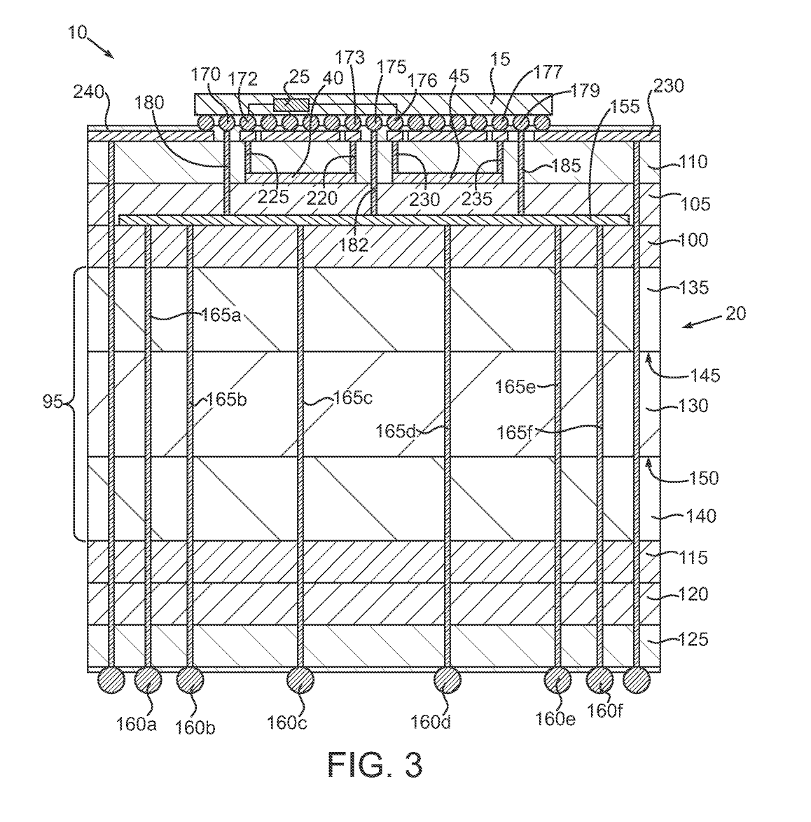

A physical implementation of the semiconductor chip device 10 that takes advantage of some available space within a circuit board 20 to position the inductors 40 and 45 may be understood by referring now to FIG. 3, which is a sectional view. FIG. 3 depicts the semiconductor chip 15 mounted on a physical implementation of the circuit board 20 described above. Here, the semiconductor chip 15 and the circuit board 20 are not shown in correct proportions so that various features of the circuit board 20 may be more readily visible. In this illustrative embodiment, the circuit board 20 may consist of a build up design, that is, a core 95 upon which three upper build up layers 100, 105 and 110 and three lower build up layers 115, 120 and 125 may be fabricated, the terms “upper” and “lower” being arbitrary. The core 95 itself may consist of a central portion 130 and two stack portions 135 and 140 secured thereto by adhesives or other joining techniques at the interfaces 145 and 150. The core 95 may be composed of well-known polymeric materials, such as epoxies, or ceramics. The build up layers 100, 105, 110, 115, 120 and 125 may be composed of the aforementioned well-known epoxies or other types of resins.

The buildup layers 100, 105 and 110 may be configured to provide various electrical routing functionalities. For example, the layer 100 may be configured to provide a ground plane 155. The ground plane 155 may consist of one or more conductors providing ground connections to input/outputs (I/O) 160a, 160b, 160c, 160d, 160e and 160f of the circuit board 20 by way of the corresponding conductive pathways 165a, 165b, 165c, 165d, 165e and 165f. The I/Os 160a, 160b, 160c, 160d, 160e and 160f may be the solder balls as depicted, conductive pillars with our without solder caps, pin grid arrays, land grid arrays or virtually any other type of interconnect structures. It should be understood that the conductive pathways 165a, 165b, 165c, 165d, 165e and 165f may consist of a variety of different types of conductive mechanisms, such as, plated through-holes, at least within the confines of the core 95, and some combination of metallization and conductive vias within the various build up layers 100, 105, 110, 115, 120 and 125. The ground plane 155 may also provide ground connection to some of the plural interconnect or I/O structures that electrically connect the semiconductor chip 15 to the circuit board 20, such as the I/O structures 170, 172, 173, 175, 176, 177 and 179. The I/O structures 170, 172, 173, 175, 176, 177 and 179 may be solder bumps, micro bumps, conductive pillars with or without solder caps or others. The I/O structures 170, 175 and 179 may be tied to the ground plane 155 by way of electrical pathways 180, 182 and 185, which like the pathways 165a, 165b, 165c, 165d, 165e and 165f, may be single conductors or some combination of metal traces and interlevel conductive vias as desired.

The build up layer 105 may be used to provide routing for the conductive pathways 180, 182 and 185 for the ground connections. In addition, the build up layer 105 can serve as a location for the physical patterning of the aforementioned inductors 40 and 45. It should be understood that in this illustrative embodiment, the aforementioned regulator logic 25 is incorporated into the semiconductor chip 15. Thus, the inductor 40 may receive at the I/O structure 172 a voltage input from the regulator logic 25 and provide RV_{DD} at, for example, the I/O structure 173. The inductor 45 may similarly receive at I/O 176 a voltage input from the regulator logic 25 and deliver the regulated voltage RV_{DD} to the I/O structure 177. The inductor 40 may be connected to the I/O structures 172 and 173 by way of conductor structures 220 and 225, which may be conductive vias or other conductor structures. The conductor structures 220 and 225 may be connected to the I/O structures 200 and 205 by portions of a power plane 230 that is fabricated in conjunction with the build up layer 110. The interconnect structures 230 and 235 may be similarly connected to portions of the power plane 230. The power plane 230 may be topped with a solder resist layer 240 as necessary in order to facilitate the fabrication of the I/O structures 170, 172, 173, 175, 176, 177 and 179.

The skilled artisan will appreciate that it is advantageous to be able to place the inductors 40 and 45 onboard the circuit board 20 so that they are substantially or at least somewhat vertically aligned a portion(s) of the semiconductor chip 15 required regulated power. It is further advantageous to position the regulator logic 25, and particularly the switching logic thereof, on the semiconductor chip 15 and similarly near the portion(s) of the semiconductor chip 15 requiring regulated power. Both of these routing choices will tend to reduce parasitics.

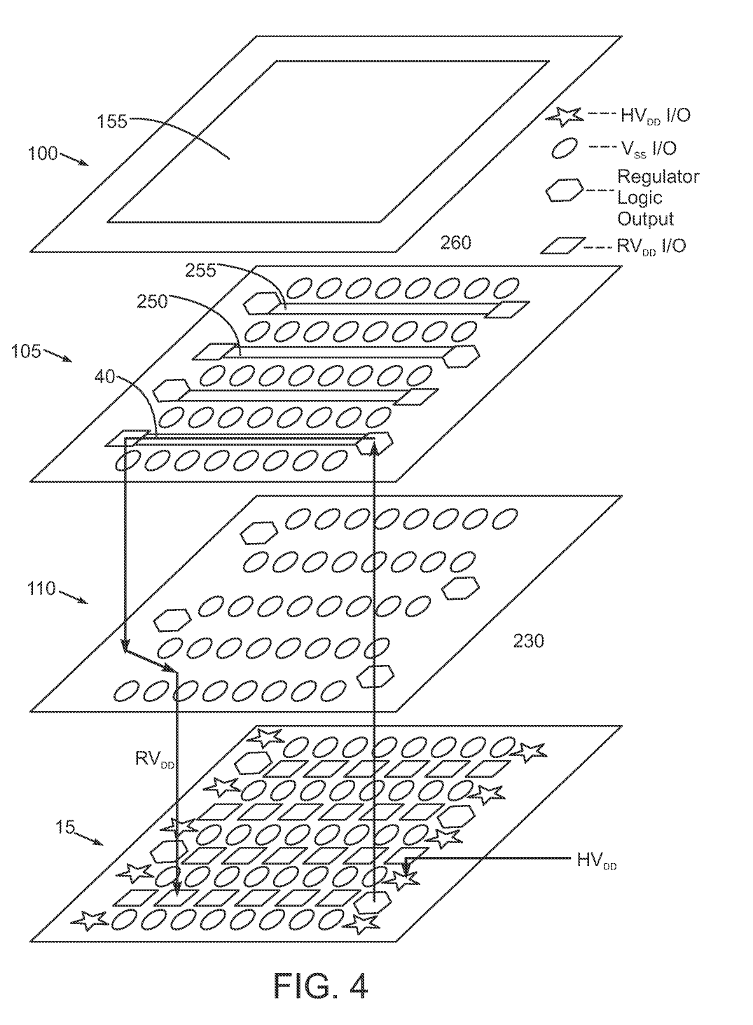

Additional details of the inductor 40 may be understood by referring now to FIG. 4. The following description of the inductor 40 will be illustrative of the inductor 45 and other inductors as will become apparent. FIG. 4 is a schematic representation of the build up layers 100, 105, 110 and a semiconductor chip flipped over from the orientation depicted in FIG. 3 and exploded. Thus, the build up layer 100 is shown at the top and the build up layers 105, 110 and the semiconductor chip 15 are shown at successively lower positions. The build up layer 100 includes the aforementioned ground plane 155, which here is depicted as a sheet or plane. Before turning to a description of the depictions of the build up layers 105, 110 and the semiconductor chip 15, it will be useful to refer briefly to the symbol key provided in FIG. 4. Geometric symbols are used to represent different types of I/O sites in a given build up layer or the semiconductor chip 15. The star symbol ⋆ represents I/O site for the HV_{DD} power, the oval symbol ◯ represents an I/O site for ground or V_{SS}, the hexagonal symbol [symbol] represents an I/O site for the regulator logic output and the square symbol □ represents the output of the regulated voltage RV_{DD}. Now it should be understood that the various interlevel conductors such as the electrical pathways 180, 182, 185, 220, 220, etc. depicted in FIG. 3 are not shown in FIG. 4 for simplicity of illustration. Where practical, the following description of the build layers 100 and 110 and the semiconductor chip 15 will refer to a physical structure depicted in FIG. 3 to provide context. Referring to the build up layer 105, the inductor 40 may be implemented as a strip inductor as shown. Note that the inductor 40 has as an input an output of the regulator logic, which may correspond to the output from the regulator logic 25 applied to the I/O structure 172 depicted in FIG. 3. The output of the inductor 40 is the regulated voltage RV_{DD}, which corresponds to the output at the I/O 173 depicted in FIG. 3. The inductor 40 may be positioned between adjacent rows of ground or V_{SS} I/Os, which correspond for example to perhaps the electrical pathways 180, 182 and 185 depicted in FIG. 3.

Additional inductors 250, 255 and 260 may be sandwiched between or otherwise positioned between adjacent rows of V_{SS} I/Os as shown. As noted above, the number of inductors 40, 250, 255 and 260 may be many more than the four depicted. The build up layer 110 is populated with plural V_{SS} I/Os and four regulator logic output I/Os that are electrically insulated from the ground I/Os. The build up layer 110 can additionally serve as the location for the power plane 230 depicted in FIG. 3. Finally, the semiconductor chip 15 includes the HV_{DD} I/Os, plural V_{SS} I/Os, regulator logic I/Os and RV_{DD} inputs.

A typical pathway for an HV_{DD} input to the semiconductor chip through the inductor 40 and back will now be described. Note that the HV_{DD} power may be delivered to for example one of the HV_{DD} I/Os. From there, the semiconductor chip 15 by way of the regulator logic 25 depicted in FIGS. 1, 2 and 3, delivers the regulator logic output to the regulator logic output I/O of the build up layer 110 and the regulator logic I/O of the build up layer 105 where it passes through the inductor 40 to the RV_{DD} I/O of the build up layer 105 back down to the power plane 230 associated with the build up layer 110 and from there to the RV_{DD} input at the semiconductor chip 15. Of course this electrical pathway is repeated across the expanse of the semiconductor chip 15 and the build up layers 105 and 110.

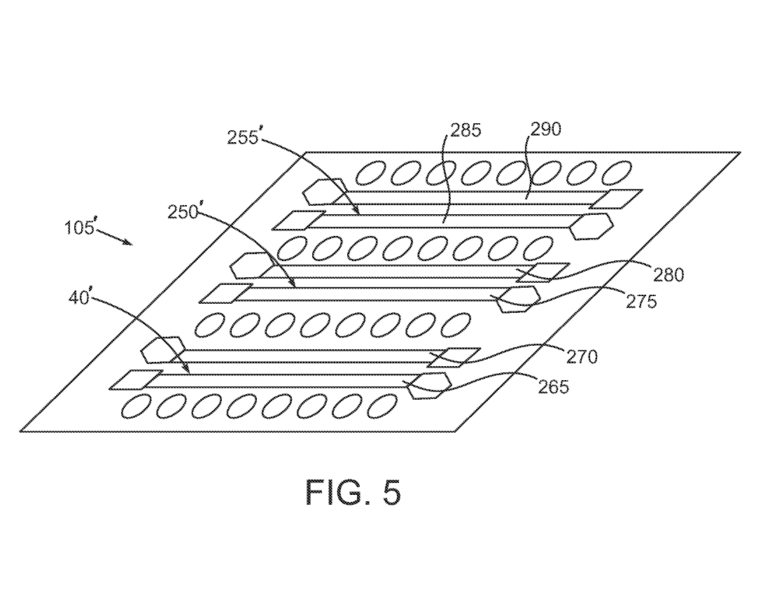

In the illustrative embodiment depicted in FIG. 4, the strip inductors 40, 250, 255 and 260 are implemented as single strips. However, reverse coupled inductors may be used as well in order to provide some greater level of inductance without dramatically increased usage of chip area. In this regard, attention is now turned to FIG. 5, which is a pictorial view of an alternate exemplary embodiment of the build up layer 105′. Here, an inductor 45′ may be implemented as two reverse inductively coupled inductor strips 265 and 270. Additional inductors 250′ and 255′ may similarly be fabricated with reverse coupled strips 275, 280, 285 and 290, respectively. Well-known switching logic or perhaps the regulator logic 25 depicted in FIG. 3 and described above may be suitably manipulated to alternatively ground one or another of the strips 265 and 270 while the other is held high and so on for the other inductors 250′ and 255′ in order to best utilize the reverse coupled strips concept.

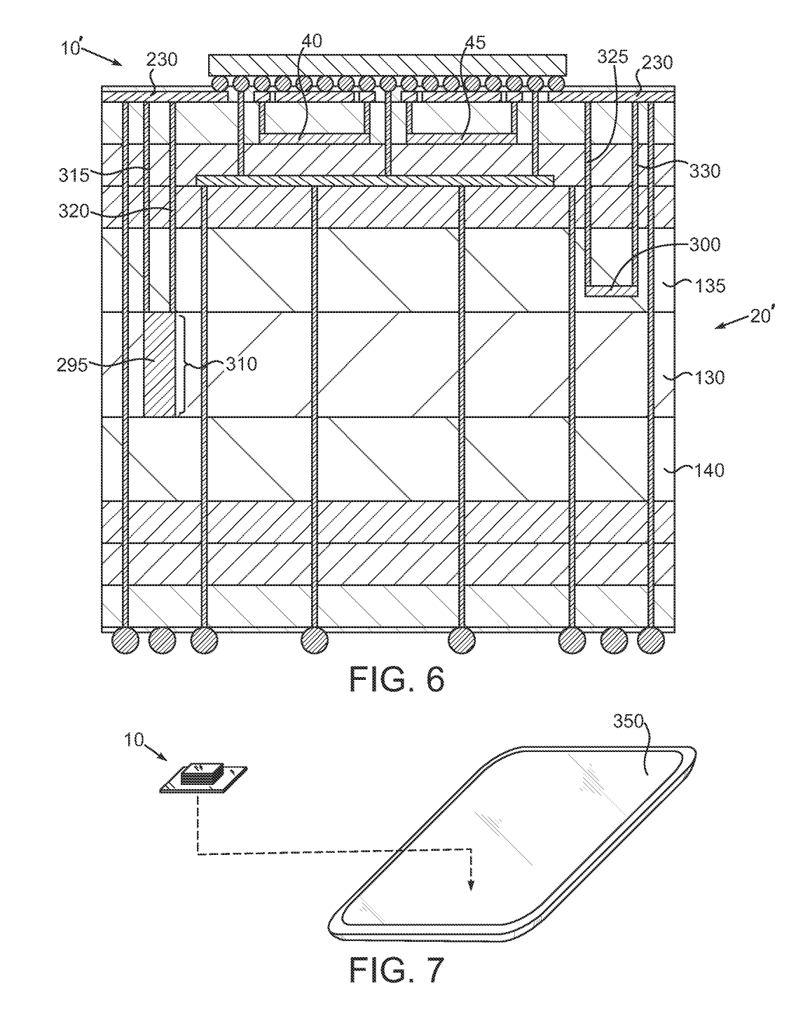

In the foregoing illustrative embodiments, the inductors 40 and 45 are implemented in one of the build up layers as strip inductors. However, it may be possible to implement circuit board-based inductors for regulator purposes in other than the build up layers. For example, and as shown in FIG. 6, which is a sectional view like FIG. 3 but of an alternate exemplary embodiment of a circuit board 20′, the inductors 40 and 45 may be fabricated in conjunction with the build up layer 110 as described above. However, two additional inductors 300 and 305 may be fabricated in conjunction with the core 95′ of the circuit board 20′. Here, the circuit board 20′ may be substantially identical to the circuit board 20 described above. However, the inductor 295 may be fabricated in the core 95′ and in particular the core portion 130 as a drop-in component. This may be accomplished by fabricating a suitable bore 310 in the core portion 130 and thereafter dropping in the discrete inductor 295 as a component. Thereafter, electrical connections between the electrical pathways 315 and 320 may be established to and from the inductor 295. These pathways 315 and 320 may connect to the power plane 230 or to whatever connections are appropriate in order to enable the inductor 295 to function like the inductors 40 and 45 for example. In contrast, the inductor 300 may be fabricated as a single or multi-turn coil within the core stack portion 135 or the other core stack portion 140 as desired. Here, the inductor coil 300 may be fabricated using well-known metal fabrication techniques such as those that might be used to fabricate any of the conductor structures within the circuit board 20′ during, for example, the manufacture of the core portion 135 by resin deposition and curing or other techniques. Thereafter, the electrical pathways 325 and 330 may be established to the inductor 300 and connect to the power plane 230 or whatever I/O structures are appropriate to enable the inductor 300 to serve as a regulator inductor, such as the inductors 40 and 45.

The various conductors disclosed herein such as the inductors 40 and 45 and other inductors, the conductive pathways 165a, 165b, 165c, 165d, 165e, 165f, 180, 182, 185, 220, 220, and the ground plane 155 and the power plane 230 may be composed of a variety of electrically conductive materials, such as copper, aluminum, gold, silver, platinum, palladium, nickel, tantalum, combinations of these or others, and fabricated using well-known fabrication techniques, such as plating, chemical vapor deposition, physical vapor deposition, along with suitable patterning techniques, such as masking and chemical etching or laser ablation, or even lift off processes.

It should be understood that the semiconductor chip 15 depicted in FIGS. 1, 2 and 3 may be used to perform electronic functions. The types of electronic functions are virtually limitless and include operations such as floating point calculations, memory management, I/O functions, analog processing and power management to name just a few.

Any of the disclosed embodiments of the semiconductor chip device 10 or 10′ may be incorporated into another electronic device such as the electronic device 350 depicted in FIG. 7. Here, the semiconductor chip device 10 is shown exploded from the electronic device 350. The electronic device 350 may be a computer, a server, a hand held device, or virtually any other electronic component.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
fabricating at least one inductor in a circuit board;
coupling a semiconductor chip to the circuit board;
electrically coupling the at least one inductor to the semiconductor chip; and
electrically coupling regulator logic to the at least one inductor, the regulator logic and the at least one inductor being operable to deliver a regulated voltage to the semiconductor chip.

2. The method of claim 1, wherein the circuit board comprises a package substrate.

3. The method of claim 1, comprising fabricating at least two inductors in the circuit board and electrically coupling each of the at least two onboard inductors to the regulator logic.

4. The method of claim 1, wherein the regulator logic comprises a controller and at least two switching transistors.

5. The method of claim 1, wherein the at least one inductor is fabricated as a first strip.

6. The method of claim 5, wherein the at least one inductor is fabricated as a second strip inductively coupled to the first strip.

7. The method of claim 1, wherein the circuit board comprises a core and at least one build up layer, the at least inductor being fabricated in the at least one build up layer.

8. The method of claim 1, wherein the circuit board comprises a core and at least one build up layer, the at least inductor being fabricated in the core.

9. The method of claim 1, wherein the regulator logic is in the semiconductor chip.

10. The method of claim 9, wherein the semiconductor chip comprises a portion requiring the regulated voltage, the at least one inductor being positioned in spatial alignment with and the regulator logic being positioned near the portion.

11. A method providing a regulated voltage to a semiconductor chip, comprising:
coupling the semiconductor chip to a circuit board, the circuit board having at least one onboard inductor;
electrically coupling the at least one inductor to the semiconductor chip; and
electrically coupling regulator logic to the at least one inductor and supplying input voltage to the regulator logic, the regulator logic and the at least one inductor being operable to deliver a regulated voltage to the semiconductor chip based on the input voltage.

12. The method of claim 11, wherein the circuit board comprises a package substrate.

13. The method of claim 11, wherein the circuit board comprises at least two onboard inductors, the method including electrically coupling each of the at least two onboard inductors to the regulator logic.

14. The method of claim 11, wherein the regulator logic comprises a controller and at least two switching transistors.

15. The method of claim 11, wherein the at least one inductor comprises a first strip.

16. The method of claim 15, wherein the at least one inductor comprises a second strip inductively coupled to the first strip.

17. The method of claim 11, wherein the circuit board comprises a core and at least one build up layer, the at least inductor being in the at least one build up layer.

18. The method of claim 11 wherein the circuit board comprises a core and at least one build up layer, the at least inductor being in the core.

19. The method of claim 11, comprising performing an electronic function with the semiconductor chip.

20. An apparatus, comprising:
a circuit board having at least one onboard inductor;
a semiconductor chip coupled to the circuit board and electrically coupled to the at least one inductor; and
regulator logic electrically coupled to the at least one inductor, the regulator logic and the at least one inductor being operable to deliver a regulated voltage to the semiconductor chip.

21. The apparatus of claim 20, wherein the circuit board comprises a package substrate.

22. The apparatus of claim 20, wherein the circuit board comprises at least two onboard inductors, each of the at least two onboard inductors being electrically coupled to the regulator logic.

23. The apparatus of claim 20, wherein the regulator logic comprises a controller and at least two switching transistors.

24. The apparatus of claim 20, wherein the at least one inductor comprises a first strip.

25. The apparatus of claim 24, wherein the at least one inductor comprises a second strip inductively coupled to the first strip.

26. The apparatus of claim 20, wherein the circuit board comprises a core and at least one build up layer, the at least inductor being positioned in the at least one build up layer.

27. The apparatus of claim 20, wherein the regulator logic is in the semiconductor chip.

28. The apparatus of claim 20, comprising an electronic device coupled to the circuit board.

29. An apparatus, comprising:
a circuit board having at least one onboard inductor; and
whereby the circuit board is adapted to from part of a voltage regulator when coupled to an integrated circuit including regulator logic.

30. A semiconductor chip, comprising:
regulator logic; and
whereby the semiconductor chip being adapted to be coupled to an inductor included in a circuit board, and the regulator logic when coupled to the at least one inductor being operable to deliver a regulated voltage to the semiconductor chip.
